(19) United States
(12) Patent Application Publication
(10) Pub. No.: US 2003/0226252 A1
(43) Pub. Date: Dec. 11, 2003

(54) Packaging method for X-ray image sensory systems

(76) Inventor: Kuo-Fu Liao, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/162,866

(22) Filed: Jun. 6, 2002

(51) Int. Cl. H05K 3/20; H05K 3/02

(52) U.S. Cl. 29/831; 29/846

(57) ABSTRACT

A packaging method for an X-ray image sensory system having an X-ray conversion module and a TFT panel includes steps of manufacturing the X-ray conversion module and TFT panel separately and then connecting the above components together. A pixel-based connecting method is then applied to connect the aforementioned conversion module and the TFT panel. The step of connecting the conversion module and TFT panel is pixel-based, representing that the distribution and the size of conductive bumps and boundary frames are based on every corresponding pixel, thereby to collect and output converted X-ray signals on a pixel basis.

### BACKGROUND OF THE INVENTION

1. Field of the Invention

The present invention relates to a packaging method for X-ray image sensory systems, and more particularly, to a packaging method for connecting separately manufactured components of an X-ray sensory system.

2. Description of Prior Arts

An X-ray image sensory system converts the input X-rays into electrical or visible light signals. The converted signals are then collected separately to obtain the mapping of the X-ray dosage. A TFT panel is then used for outputting the obtained mapping. As described in the previous operation, the TFT panel is not used in converting X-rays to electrical or visible light signals.

The conventional process for manufacturing X-ray image sensory systems is to manufacture the TFT panel first. As the TFT panel is ready, the diodes, X-ray conversion layers or scintillators are then manufactured on top of the panels. There is a severe problem with this type of serial manufacturing process. During the manufacturing process, mistakes in any step will render the entire product useless. This may cause very low yields and high production costs.

In general, the TFT panels are manufactured at the temperature below 350 degrees Celsius. If the required working temperature for manufacturing steps for other components exceed the tolerance temperature of panel, the panels may suffer permanent damages. Furthermore, the metal layer on the TFT panels for growing diodes can be easily damaged by the chemicals used in the successive steps. Because the entire manufacturing process of an X-ray image sensory system is with many risks of damages, the manufacturing yields are consequently low, thus unit production cost is high. To improve the low yield situation, the present manufacturing process for X-ray image sensory systems usually follows very strict guidelines, which, in turn, place severe constraints on selections of the material and application methods for successive steps.

### SUMMARY OF THE INVENTION

The present invention is to provide a packaging method for X-ray image sensory systems. The packaging method allows each component of the X-ray image sensory systems to be manufactured separately. For example, the X-ray conversion module and the TFT panels can be manufactured separately. A pixel-based connecting method is then applied to connect the aforementioned conversion module and the TFT panel. The pixel-based connecting method employs electrically conductive bumps or boundary frames to connect the TFT panel and the conversion module on a pixel basis. The signals converted by the conversion module can then be transmitted through the conductive bumps to the TFT panels.

For the aforementioned purpose, the present invention provides a packaging method for the X-ray image sensory systems. The X-ray image sensory system includes one or more x ray conversion modules for converting the input X-ray into electrical or visible light signals, and a TFT panel for collecting and outputting the signals. The X-ray conversion modules and the TFT panels are manufactured separately, thereafter are electrically connected by the conductive bumps or boundary frames for electrical or visible light transmission.

These and other objectives of the present invention will no doubt become obvious to those of ordinary skill in the art after reading the following detailed description of the preferred embodiment which is illustrated in the various figures and drawings.

### BRIEF DESCRIPTION OF THE DRAWINGS

FIG. 1A is a schematic diagram of the first embodiment of the present invention.

FIG. 1B is a schematic diagram of another embodiment of the present invention.

FIG. 1C is a schematic diagram of another embodiment of the present invention.

FIG. 2A is a schematic diagram of another embodiment of the present invention.

FIG. 2B is a schematic diagram illustrating the embodiment of FIG. 2A after connection.

FIG. 3A is a schematic diagram of another embodiment of the present invention.

FIG. 3B is a schematic diagram illustrating the embodiment of FIG. 3A after connection.

FIG. 4A is a schematic diagram of another embodiment of the present invention.

FIG. 4B is a embodiment of FIG. 4A after connection.

### DETAILED DESCRIPTION OF THE PREFERRED EMBODIMENT

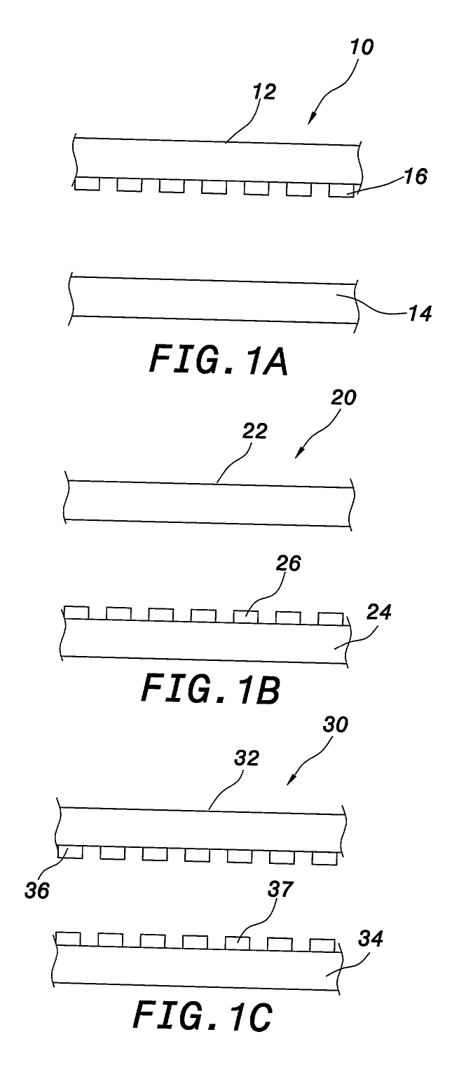

FIG. 1A shows a schematic diagram of a preferred embodiment 10 according to the present invention. The embodiment 10 includes an X-ray conversion module 12 for converting the input x ray (not shown), and a TFT panel 14 for collecting and outputting the converted signals. The X-ray conversion module 12 and the TFT panel 14 are manufactured separately. The X-ray conversion module 12 includes at least one conductive bump 16, each of which corresponds to one pixel. The X-ray conversion module 12 and the TFT panel 14 utilize the conductive bumps 16 for connection. The electrical signals, converted from the input X-ray by the conversion module 12, can travel through the conductive bumps 16, and be collected and outputted by the TFT panel 14. Because the size and the distribution of the conductive bumps 16 depend on those of the pixels on the TFT panels 14, the packaged X-ray image sensory system, including an X-ray conversion module 12 and a TFT panel 14, can output the pixelized signals.

FIG. 1B shows a schematic diagram of another embodiment 20 of the present invention. The embodiment 20 also includes an X-ray conversion module 22 for converting the input X-ray (not shown), and a TFT panel 24 for collecting and outputting the converted signals. The X-ray conversion module 22 and the TFT panel 24 are also manufactured separately. The embodiment differs from the one depicted in FIG. 1A in that the conductive bumps 26 are placed on the TFT panels 24. Each conductive bump 26 corresponds to a pixel. The conversion module 22 is connected to the TFT panel 24 through the conductive bumps 26. The electrical signal, converted from the input X-ray by the X-ray conversion module 22, can travel through the conductive bumps 26, and be collected and outputted by the TFT panel 24. Because the size and the distribution of the conductive bumps 26 depend on those of the pixels on the TFT panels 24, the packaged X-ray image sensory system, including an X-ray conversion module 22 and a TFT panel 24, can output the pixelized signals.

FIG. 1C shows a schematic diagram of another embodiment 30 of the present invention. The embodiment 30 also includes an X-ray conversion module 32 for converting the input X-ray and a TFT panel 34 for collecting and outputting the converted signals. The X-ray conversion module 32 and the TFT panel 34 are also manufactured separately. The embodiment 30 differs from its counterpart 10 and 20 shown in FIGS. 1A and 1B in that the conductive bumps 36 and 37 are placed on both the conversion module 32 and the TFT panels 34. Each conductive bump 36 corresponds to another conductive bump 37, which, in turn, corresponds to a pixel. Because the size and the distribution of the conductive bumps 36 depend on those of the bumps 37 on the TFT panels 24, which, in turn, depend on the pixels on the TFT panels 24, the packaged X-ray image sensory system 30, including an X-ray conversion module 32 and a TFT panel 34, can output the pixelized signals.

The conductive bumps 16,26,36 and 37 in the FIGS. 1A, 1B, and 1C, and their conversion modules 12, 22, 32, and the TFT panels 14, 24, 34 could be glued together by a conductive glue, or using pressure or heat for attachment.

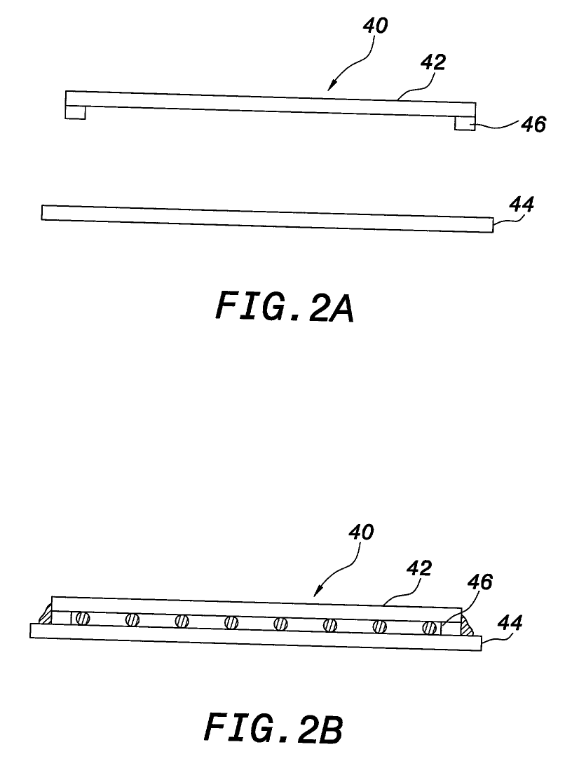

FIGS. 2A and 2B show schematic diagrams illustrating another preferred embodiment 40 of the present invention before and after connection. The embodiment 40 includes an X-ray conversion module 42 for converting the input X-ray and a TFT panel 44 for collecting and outputting the converted signals. The X-ray conversion module 42 and the TFT panel 44 are manufactured separately. The X-ray conversion module 42 includes a boundary frame 46 for connecting to the TFT panel 44. After the connection, there is a gap 47 between the conversion module 42 and the TFT panel 44, as shown in FIG. 2B. The present invention includes a step of placing a supporter 48 in the gap 47, so that the TFT panel 44 can firmly support the conversion module 42. The supporter 48 could be a glass ball or a fiber rod. In addition to the supporter 48, a sealing glue 49 is applied to connect the boundary frame 46 to the TFT panel 44, as well as connecting the conversion module 42 to the TFT panel 44. The present invention also includes a step of allowing the gap 47 to be a vacuum gap after sealing the boundary frame 46 with the glue 49. The vacuum gap 47 is necessary for the field emission at the X-ray conversion module 42. The height of the supporter 48 should be approximately the same as that of the boundary frame 46 for the purpose of ensuring a tight connection between the conversion module 42 and the TFT panel 44, and, thus to keep the gap 47 be vacuum.

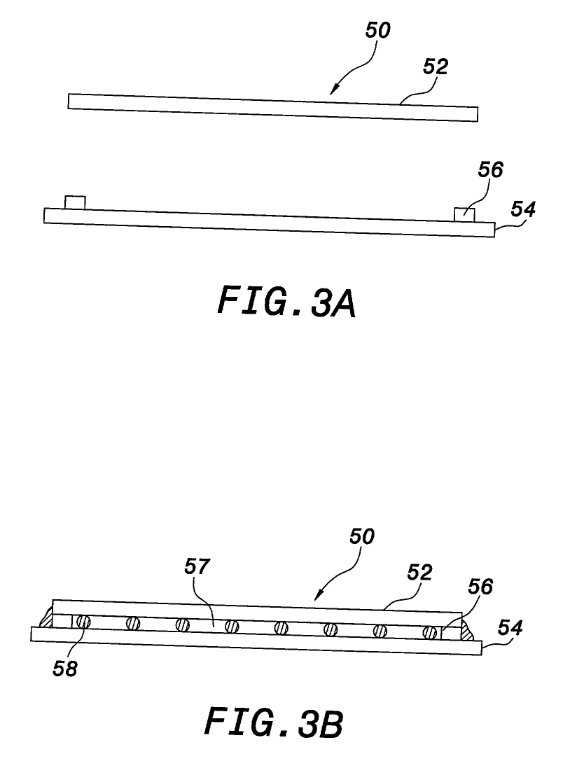

FIGS. 3A and 3B show schematic diagrams of illustrating another embodiment 50 of the present invention before and after connection. The embodiment 50 includes an X-ray conversion module 52 for converting the input X-ray and a TFT panel 54 for collecting and outputting the converted signals. The X-ray conversion module 52 and the TFT panel 54 are manufactured separately. The TFT panel 54 includes a boundary frame 56 for connecting to the conversion module 54. After the connection, there is a gap 57 between the conversion module 52 and the TFT panel 54, as shown as in FIG. 3B. The present packaging method further includes a step of placing at least one supporter 58 in the gap 57, so that the TFT panel 54 can firmly support the conversion module 52. The supporter 58 could be a glass ball or a fiber rod. In addition to the supporter 58, a sealing glue 59 is applied to connect the boundary frame 56 to the conversion module 52, as well as connect the TFT panel 54 to the conversion module 52. The present invention also includes a step of enabling the gap 57 to be a vacuum gap after sealing the boundary frame 56 with the glue 59. The vacuum gap 57 is necessary for the field emission at the X-ray conversion module 52. The height of the supporter 58 should be approximately the same as that of the boundary frame 56. This is to ensure the tight connection between the conversion module 52 and the TFT panel 54, and keep the gap 57 in the vacuum state.

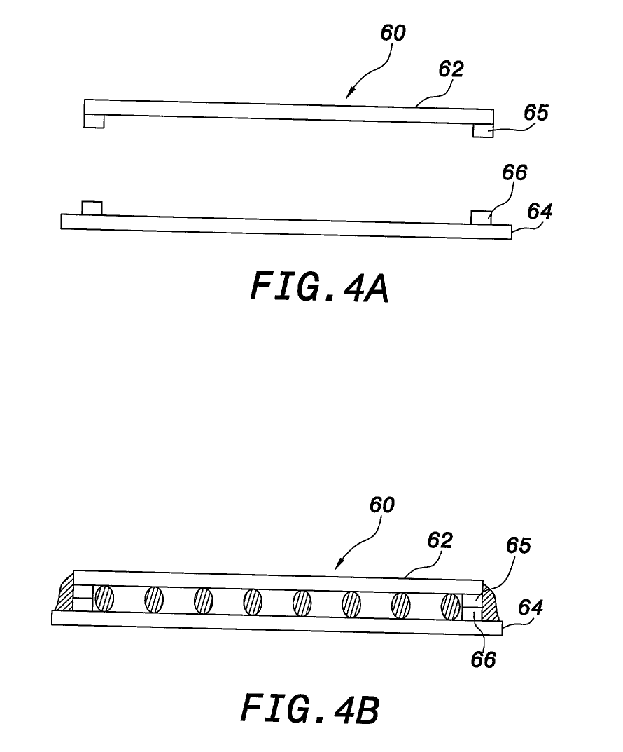

FIGS. 4A and 4B show schematic diagrams of another embodiment 60 of the present invention before and after connection. The embodiment 60 includes an X-ray conversion module 62 for converting the input X-ray and a TFT panel 64 for collecting and outputting the converted signals. The X-ray conversion module 62 and the TFT panel 64 are manufactured separately. The X-ray conversion module 62 and the TFT panel 64 include a boundary frame 65 and 66, respectively. The boundary frame 65 and 66 are then connected together. After the connection, there is a gap 67 between the conversion module 62 and the TFT panel 64, as shown in FIG. 4B. The present embodiment is formed by another step of placing a supporter 68 in the gap 67, so that the TFT panel 64 can firmly support the conversion module 62. The supporter 68 could be a glass ball or a fiber rod. In addition to the supporter 68, a sealing glue 69 is applied to connect the boundary frame 66 to the X-ray conversion module 62, as well as connect the TFT panel 64 to the X-ray conversion module 62. The present invention also includes another step of forming a vacuum gap 67 between the X-ray conversion module 62 and the TFT panel 64 after sealing the boundary frame 66 with the sealing glue 69. The vacuum gap 67 is necessary for the field emission at the X-ray conversion module 62. Further, the height of the supporter 68 should be approximately the same as that of the boundary frame 66, for ensuring a tight connection between the conversion module 62 and the TFT panel 64, and maintaining the gap 67 to be vacuum.

The boundary frames 46, 56, 65 and 66 could be placed on the opposing sides or all sides around the X-ray conversion modules 42, 52, 62 and the TFT panels 44, 54, 64. This kind of placement is to ensure the tight connection between the conversion modules 42, 52, 62 and the TFT panels 44, 54, 64.

The X-ray conversion modules 12, 22, 32, 42, 52, and 62 could either convert the input X-rays into the visible light signals first or into electrical signals directly. The visible light signals could be detected by a photodiode, thereby generating corresponding electrical signals. This is the so-called in-direct conversion. Alternatively, the input X-ray could be directly converted to electrical signals. Regardless of the conversion type, the guiding rule is to ensure that the converted signals could be completely collected and outputted by the TFT panels 14, 24, 34, 44, 54, and 64.

Compared to the prior arts, the present invention allows separately manufacturing the components of the X-ray image sensory systems and assembling them together for the purpose of improving the yield of the product. Further, the present invention is a pixel-based connecting method while connecting the aforementioned conversion module and the TFT panel. The pixel-based connecting method employs electrically conductive bumps or boundary frames to connect the pixels of the TFT panel and the conversion module. In the case of boundary frames, the present invention also includes steps of applying a sealing glue between the conversion module and TFT panel, and keeping the gap between the conversion module and the TFT panel be vacuum, thereby necessitating the field emission of the conversion module. Because the present invention allows the components to be manufactured separately, the manufacturing of one component will not affect others. Therefore, the choice of materials and process in manufacturing each individual component is more flexible. Furthermore, as the components are manufactured separately, one damaged component due to manufacturing mistakes will not affect other components, thus, the damaged component is replaceable and the yield of whole image sensory system can be improved to lower the production cost.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A packaging method for an X-ray image sensory system having an X-ray conversion module for converting input X-rays into electrical signals and a TFT panel for collecting and outputting the converted electrical signals, the packaging method comprising steps of:
manufacturing the X-ray conversion module and the TFT panel separately; and
connecting the X-ray conversion module and the TFT panel on a pixel basis.

2. The packaging method as in claim 1, wherein X-ray conversion module comprises at least one conductive bump corresponding to a pixel.

3. The packaging method as in claim 1, wherein the TFT panel comprises at least one conductive bump corresponding to a pixel.

4. The packaging method as in claim 1, wherein the X-ray conversion module converts the input X-ray signals into electrical signals.

5. A packaging method for an X-ray image sensory system having an X-ray conversion module for converting input X-rays into electrical signals and a TFT panel for collecting and outputting the converted electrical signals, the packaging method comprising:
manufacturing the X-ray conversion module and the TFT panel separately; and
connecting the X-ray conversion module and the TFT panel.

6. The packaging method as in claim 5, wherein the X-ray conversion module further comprises a boundary frame for connecting the TFT panel.

7. The packaging method as in claim 5, wherein the TFT panel further comprises a boundary frame for connecting the said X-ray conversion module.

8. The packaging method as in claim 5, wherein both the X-ray conversion module and the TFT panel comprise a boundary frame for connecting with each other.

9. The packaging method as in claim 5, wherein the boundary frame further comprises a sealing glue thereon for connecting with the TFT panel.

10. The packaging method as in claim 5 further comprising a step of disposing at least one supporter between the X-ray conversion module and the TFT panel.

11. The packaging method as in claim 10, wherein the supporter is of approximately as high as the boundary frame.

12. The packaging method as in claim 10, wherein the supporter is a glass ball.

13. The packaging method as in claim 10, wherein the supporter is a fiber rod.

14. The packaging method as in claim 5, further comprising a step of forming a vacuum gap disposed between the conversion module and the TFT panel.
